(19) United States
(12) Patent Application Publication
(10) Pub. No.: US 2026/0352792 A1
(43) Pub. Date: Nov. 5, 2026

(54) CAMERA SYSTEM

(71) Applicant: ams-OSRAM International GmbH, Regensburg (DE)

(72) Inventors: Florian KOLB, Jena (DE); Stefan HADRATH, Falkensee (DE); Jozef PULKO, Premstätten (AT); Martin DANIELS, Berlin (DE)

(21) Appl. No.: 19/487,287

(22) PCT Filed: Jun. 18, 2024
(86) PCT No.: PCT/EP2024/066922

§ 371 Date: Nov. 24, 2025

(30) Foreign Application Priority Data
Jun. 23, 2023 (DE) 10 2023 116 560.7

(51) Int. Cl. H04N 13/254; H04N 13/00; H04N 13/243

(52) U.S. Cl. CPC H04N 13/254; H04N 13/243; H04N 2013/0081

(57) ABSTRACT

A camera system comprising a plurality of photodetectors and a plurality of optical channels is specified, wherein the photodetectors are arranged spaced apart from one another in a detection plane, to each one of the plurality of photodetectors one of the optical channels is assigned, each of the optical channels has a main viewing direction, and the optical channels comprise a plurality of different main viewing directions. For example, the camera system is integrated in a display using micro-LEDs as light-emitting pixels.

The present application refers to a camera system.

Many electronic devices such as smartphones are provided with a camera facing the user, for example for video calls or user identification. Typically, the camera is arranged laterally beside the display of the device. This reduces the space available for the display on the device and also leads to a parallax between the camera and the center of the screen (e.g. the image of a person during a video call).

An object to be solved is to provide a camera system that is flat and can be integrated in or placed behind a pane, for example of a display screen.

This object is inter alia obtained by a camera system according to claim 1. Further configurations and expediencies are subject of the dependent claims.

A camera system comprising a plurality of photodetectors and a plurality of optical channels is specified. The photodetectors are in particular configured to be sensitive to radiation from an object to be imaged by the camera system. For example, the radiation is electromagnetic radiation in the visible spectral range and/or in the infrared spectral range.

According to at least one embodiment of the camera system, the photodetectors are arranged spaced apart from one another in a detection plane. For example, the photodetectors are individual devices placed on a common carrier, such as a printed circuit board or a display backplane. The photodetectors may each comprise one or a plurality of photosensitive regions. The photodetectors distributed over the detection plane taken together provide the pixels of the camera system. In a conventional camera, in contrast, all photosensitive regions are formed in a single, contiguous photodetector device.

According to at least one embodiment of the camera system, each of the optical channels has a main viewing direction. For example, the main viewing direction includes an angle to a normal to the detection plane in a range from 0° to 30°. For example, the optical channels are configured to converge the radiation from an object to be imaged onto the assigned photodetector with one or more photosensitive regions.

Each optical channel may comprise one or a plurality of micro-optical elements. Thus, a beam path from an object to be imaged to one of the photodetectors passes one or more micro-optical elements. For example, the micro-optical elements are microlenses or optical elements based on meta-lenses or meta-materials. In particular with meta-lenses or meta-materials, a single micro-optical element may be sufficient. For example, at least one optical channel or all optical channels may comprise at least two micro-optical elements arranged at different distances from the detection plane.

For example, a micro-optical element has a lateral extent of at least 1 μm or at least 5 μm or at least 10 μm and/or at most 1 mm or at most 500 μm or at most 100 μm. In particular, the lateral extent of the micro-optical element refers to its optically effective area. Two or more of the micro-optical elements, in particular all micro-optical elements, may be formed in a common optical element or substrate, wherein the optically effective areas of adjacent micro-optical elements are laterally spaced apart from one another.

According to at least one embodiment of the camera system, to each one of the plurality of photodetectors one of the optical channels is assigned. In particular, each of the photodetectors is only illuminated by radiation passing through exactly one of the optical channels. Thus, each of the photodetectors is sensitive to radiation impinging from a certain direction onto the camera system. For example, there is a 1:1 correspondence between the optical channels and the photodetectors.

In at least one embodiment of the camera system, the camera system comprises a plurality of photodetectors and a plurality of optical channels, wherein the photodetectors are arranged spaced apart from one another in a detection plane. One of the optical channels is assigned to each one of the plurality of photodetectors. Each of the optical channels has a main viewing direction, wherein the optical channels comprise a plurality of different main viewing directions.

Taken together, the optical channels may act similarly to the compound eye of insects. The present camera system is based on the idea that the principle of a compound eye or a compound eye camera still works if the single optical channels are distributed non-contiguously over a comparably large area. Accordingly, the photodetectors receiving the radiation from the optical channels can be distributed over a large detection area in the detection plane. Consequently, a high spatial resolution can be obtained even if the individual photodetectors do not provide any spatial resolution.

Further, the described camera system based on a plurality of optical channels can provide the functionality of a light field camera. Unlike in a conventional state-of-the-art light field camera, however, a main lens is not required. Rather, spatial resolution as well as angular resolution are implemented via the optical channels having different main viewing directions. Thus the photodetectors assigned to the optical channels are sensitive to light entering from different directions.

The signals from the photodetectors taken together can be used to reconstruct an image including a depth or 3D information.

In other words, the optical parameters of the optical channels can be designed such that the optical channels, together with the spatially distributed photodetectors, work together to form a camera based on the light field principle.

The distributed arrangement of photodetectors with associated optical channels can be integrated into or placed behind a pane such as a glass pane, for example the pane is part of a display or a projector.

The photodetectors may be arranged in the detection plane within a comparably large detection area. Due to the large surface area over which the photodetectors and associated optical channels are distributed, high resolutions can be obtained more easily than in conventional light field Cameras.

For example, a lateral extent of the detection area amounts to at least 2 cm or at least 5 cm or at least 10 cm. Thus, a large number of photodetectors may be used to obtain a high spatial and angular resolution. For example, the camera system comprises at least 10,000 photodetectors or at least 100,000 photodetectors or at least 1,000,000 photodetectors or at least 10,000,000 photodetectors.

According to at least one embodiment of the camera system, light emitters are arranged at least in some interspaces between two adjacent photodetectors in a top view onto the camera system. A top view is a view along the normal to the detection plane.

For example, the light emitters are pixels of a display or a projector. In other words, the camera system may be integrated in a display or projector. For example, a pane covering the display may also form at least part of the optical channels. Thus, the light emitted by the pixels of the display may pass the same pane as the light from the object to be detected impinging onto the photodetectors forming the pixels of the camera system, but at different, intermixed positions.

For example, a micro-optical element of the optical channel has a lateral extent that is smaller than or equal to a center-to-center distance of adjacent light emitters, in particular smaller than or equal to an edge-to-edge distance between adjacent light emitters. Thus, one micro-optical element converging the radiation onto the associated photodetector may be positioned between adjacent light emitters of the display in a top view onto the camera system. The light emitters may form the pixels of the display, so that the center-to-center distance of adjacent light emitters may also be referred to as pixel pitch of the display.

According to at least one embodiment of the camera system, the light emitters are micro-LEDs. Alternatively or in addition, one or more of the light emitters or even all of the light emitters may be lasers, for example surface emitting lasers such as vertical cavity surface emitting lasers (VCSELS).

As a broad definition, a micro-LED could be seen as any light emitting diode (LED)—generally not a laser—with a particularly small size. In particular, the micro-LED, for example its active region configured to emit the radiation during operation may comprise organic or anorganic materials.

As a rule—and this is a very important criterion in addition to size—a growth substrate is removed from micro-LEDs, so that typical heights of such micro-LEDs are in the range of 1.5 μm to 10 μm, for example.

In principle, a micro-LED does not necessarily have to have a rectangular radiation emission surface. Generally, for example, an LED could have a radiation emission surface in which, in plan view of the layers of the layer stack, any lateral extent of the radiation emission surface is less than or equal to 100 μm or less than or equal to 70 μm.

For example, in the case of rectangular micro-LEDs, an edge length—especially in plan view of the layers of the layer stack-smaller than or equal to 70 μm or smaller than or equal to 50 μm is often cited as a criterion. In particular, the edge length may be even smaller than 20 μm or smaller than 10 um.

Mostly, such micro-LEDs are provided on wafers with-for the micro-LED non-destructively-detachable holding structures. Micro-LEDs are particularly suited for displays. The micro-LEDs form pixels or subpixels and emit light of a defined color.

Different ways of spelling micro-LED, e.g. μLED, μ-LED, uLED, u-LED or micro light emitting diode can be found in the relevant literature.

The fill factor in a display using micro-LEDs as light-emitting pixels can be comparatively small. For example, an edge-to-edge distance between adjacent micro-LEDs may be larger than an edge length of an individual micro-LED, for example by a factor of at least 1.5 or at least 2 or at least 3, or at least 10. Thus, there is sufficient space between adjacent micro-LEDs for the arrangement of one or more optical channels between two adjacent micro-LEDs.

According to at least one embodiment of the camera system, at least some of the light emitters are arranged in the detection plane. Consequently, during production of the camera system, the light emitters and the photodetectors may be placed on a common carrier such as a printed circuit board or a display backplane with similar or identical manufacturing methods.

For example, at least 10% or at least 50% or all light emitters are arranged in the detection plane.

According to at least one embodiment of the camera system, at least some of the light emitters are arranged on a substrate that is spaced apart from the detection plane. For example, the substrate is transparent to radiation in the visible and/or infrared spectral range.

According to at least one embodiment of the camera system, at least some of the light emitters are arranged at a larger distance from the detection plane than at least one optical element of one of the optical channels. In particular, at least 10% or at least 50% or all of the light emitters may be arranged at a larger distance from the detection plane than at least one optical element of one of the optical channels.

According to at least one embodiment, the camera system comprises a radiation source configured to illuminate an object to be imaged. The radiation source may emit radiation in the visible and/or in the infrared spectral range. For example, the radiation is emitted as a radiation cone or a radiation pattern. For example, the radiation may be used for structured light illumination purposes, like face recognition or biometric identification, in particular independent of the ambient light. The camera system may comprise further photodetectors specifically adapted to the radiation emitted by the radiation source, for example infrared radiation. Thus, the radiation source together with the further photodetectors may form an emission-detection system invisible to the human eye.

According to at least one embodiment of the camera system, the light from the light source is directed onto the object to be imaged via a further optical channel assigned to the light source. The further optical channel may essentially be configured in the same manner as the optical channels used to illuminate the photodetectors.

For example, the optical channel may comprise a diffractive optical element. For example, the diffractive optical element may be used to create a radiation pattern from the radiation emitted by the radiation source.

According to at least one embodiment of the camera system, the camera system is configured for stereo vision.

Thus, the photodetectors with the associated optical channels are configured such that, taken together, they fulfil the function of two cameras imaging the object to be imaged from two different directions.

According to at least one embodiment of the camera system, the plurality of different main viewing directions comprises a first main viewing direction and a second main viewing direction. For example, these two main viewing directions are used for stereo vision.

According to at least one embodiment of the camera system, the optical channels having the first main viewing direction are arranged in a first region of the camera system and the optical channels having the second main viewing direction are arranged in a second region of the camera system arranged laterally beside the first region. For example, the first region corresponds to a first half of a detection area and the second region corresponds to the other half of the detection area. This arrangement allows the distance between the photodetectors used to obtain an image seen along the first main viewing direction and the photodetectors used to obtain an image seen along the second main viewing direction to be maximized. As the photodetectors can be spread over a comparably large detection area, a comparably large stereo basis can be obtained, resulting in high quality 3D imaging.

According to at least one embodiment of the camera system, in a top view onto the camera system at least one of the optical channels having the second main viewing direction is arranged between two of the optical channels having the first main viewing direction. As the present approach for the camera system does not require the arrangement of the imaging channels and the photodetectors to be contiguous, the optical channels having the first main viewing direction and the optical channels having the second main viewing direction may also be intermixed or interleaved.

For example, this intermixing could be done only for certain regions of the camera system, for example to enable stereovision only for certain areas of the total field of view of the camera system or in order to increase the depth resolution in certain areas.

According to at least one embodiment of the camera system, at least one of the photodetectors includes at least one of a photodiode, a PIN photodiode, an avalanche photodiode (APD) and a single photon avalanche diode (SPAD).

Unlike an avalanche photodiode, a SPAD is biased at a voltage higher than the breakdown voltage in reverse direction of a pn-junction. This allows a particularly high sensitivity to be obtained as the electrical field is so high that even a single charge carrier injected in the depletion layer can trigger a self-sustaining avalanche.

According to at least one embodiment of the camera system, at least one of the photodetectors includes a plurality of photosensitive regions. For example, multiple photosensitive regions may be used to increase the spatial resolution and/or the angular resolution. In addition or as an alternative, multiple photosensitive regions may be used to provide a parallel readout in order to avoid dead times after detection, for example when using an SPAD.

According to at least one embodiment of the camera system, the camera system comprises a data processing system configured to extract an image from signals obtained from the plurality of photodetectors. For example, the data processing system includes an image processing system connected to the plurality of photodetectors, for example via readout electronics. If the camera system further comprises a display, the data processing system may also be configured to control the display, for example via display control electronics.

According to at least one embodiment of the data processing system, the data processing system is configured to extract a depth information on the image. Thus, the camera system may provide features of a conventional light field camera, for example the capability of changing a focal distance or a depth of focus after the image has been taken.

According to at least one embodiment of the camera system, the data processing system is configured to extract a depth information on the image. For example, the depth information may be used to create a stereo or three-dimensional image or a three-dimensional model of the imaged scene. For example, the depth of focus may be changed in portrait photos.

The described camera system may, for example, be used for access control in particular in combination with biometric identification capabilities using an integrated radiation source.

For example, the additional depth information can be registered and used to algorithmically perform refocusing or change the depth of focus or generate 3D information.

The camera system may be used in a smartphone, an automotive or aerospace system, or any other electronic device, in particular in combination with a display of the electronic device.

As the photodetectors can be spread over the display area, there is no need to place the camera laterally beside the display.

In particular, the detection area of the camera system may large compared to conventional cameras arranged laterally beside the display. As the camera system is combined with the display, the detection area may even have the same size as the display of the electronic device without negatively affecting its design or functionality.

Furthermore, a user looking at the display simultaneously looks into the camera system so that during a video conference a conversation partner may have the impression of direct eye contact. Furthermore, the virtual origin of the camera system can be shifted algorithmically according to the position of the conversation partner on the screen as to keep up the impression of direct eye contact even when the conversation partner is moving.

Features described above in connection with at least one embodiment of the camera system can be combined with other features described in connection with at least one embodiment of the camera system unless they are contradictory.

Further features and expediencies will become apparent from the subsequent description of the exemplary embodiments in connection with the figures.

In the exemplary embodiments and figures similar or similarly acting constituent parts are provided with the same reference signs. Generally, only the differences with respect to the individual exemplary embodiments are described. Unless specified otherwise, the description of a part or aspect in one exemplary embodiment applies to a corresponding part or aspect in another exemplary embodiment as well.

### IN THE FIGURES

FIG. 1A shows an exemplary embodiment of a camera system in schematic sectional view;

FIGS. 1B and 1C show schematic illustrations explaining the operation principle of the camera system;

FIG. 2 shows an exemplary embodiment of a camera system in schematic sectional view;

FIG. 3 shows an exemplary embodiment of a camera system in schematic sectional view;

FIG. 4 shows an exemplary embodiment of a camera system in schematic sectional view;

FIG. 5 shows an exemplary embodiment of a camera system in schematic sectional view;

FIG. 6A shows an exemplary embodiment of a camera system in schematic sectional view;

FIG. 6B shows an exemplary embodiment of a camera system in schematic sectional view;

FIG. 7 shows an exemplary embodiment of a camera system in schematic sectional view; and FIG. 8 shows an exemplary embodiment of a conceptual design of the camera system.

The elements illustrated in the figures and their size relationships among one another are not necessarily true to scale. Rather, individual elements or layer thicknesses may be represented with an exaggerated size for the sake of better representability and/or for the sake of better understanding.

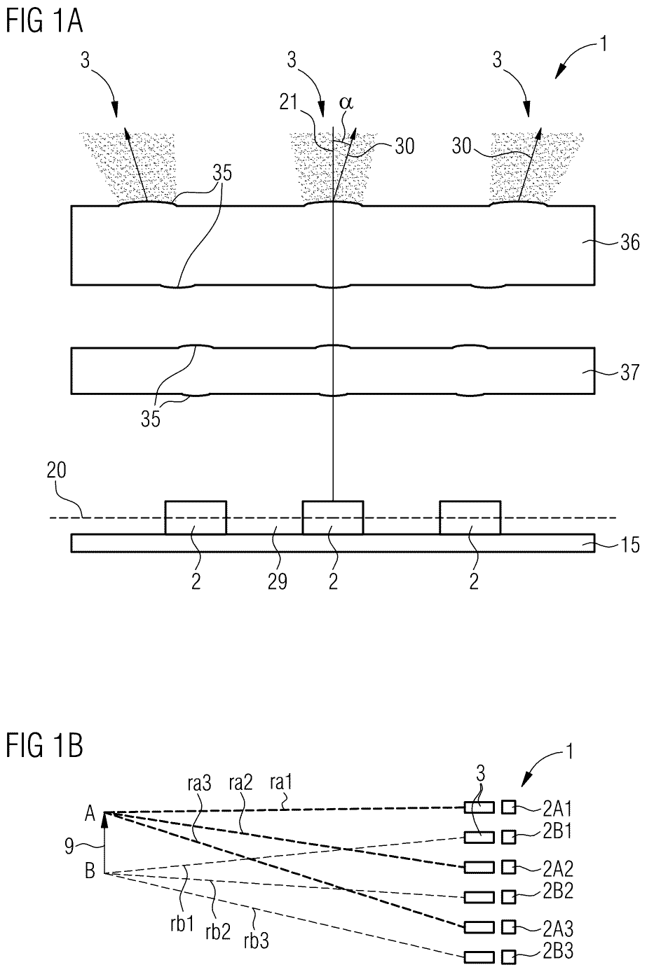

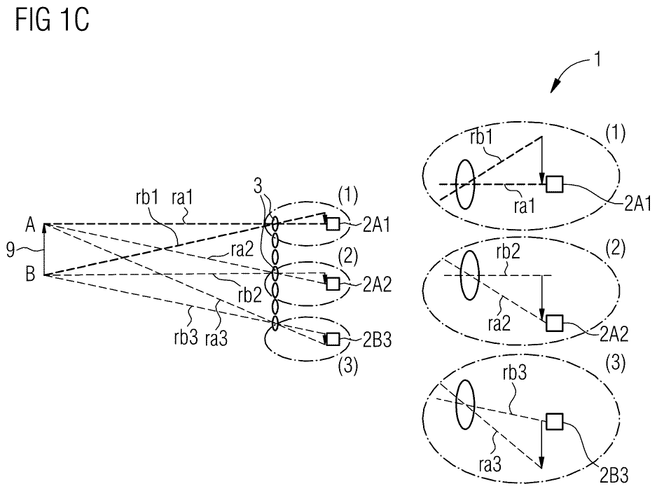

In the exemplary embodiment shown in FIG. 1A, a camera system 1 comprises a plurality of photodetectors 2 and a plurality of optical channels 3, wherein the photodetectors 2 are arranged spaced apart from one another in a detection plane 20 within a detection area. One of the optical channels 3 is assigned to each one of the plurality of photodetectors 2. Each of the optical channels 3 has a main viewing direction 30. The optical channels 3 comprise a plurality of different main viewing directions 30. For the sake of simplicity, FIG. 1A only shows three photodetectors 2 with the associated optical channels 3. In the exemplary embodiment illustrated all main viewing directions 30 are arranged at an angle a with respect to a normal 21 to the detection plane 20.

For example, the main viewing direction 30 can be set at an angle α different from 0° to the normal 21 by offsetting the centers of the micro-optical elements 35 of the optical channels 3 with respect to one another and/or with respect to the center of the photosensitive region of the associated photodetector 2.

The operation principle of the camera system 1 is illustrated in FIGS. 1B and 1C.

As shown in FIG. 1B, an object 9 to be imaged, which is illustrated as an arrow extending between points A and B, is imaged by the camera system 1.

Three light beams extending from point A labelled as ra1, ra2 and ra3 are detected by photodetectors 2A1, 2A2 and 2A3, respectively, due to the main viewing directions of the associated optical channels 3.

Likewise three beams rb1, rb2, rb3 originating from point B are detected by three different photodetectors 2B1, 2B2 and 2B3.

Consequently, different photodetectors 2 of the camera system 1 are capable of detecting beams originating from the same point of the object, but radiated in different directions towards the camera system 1. Thus, the camera system 1 may provide information on the object with both spatial and angular resolution.

The combination of optical channels 3 and associated photodetectors 2 taken together allows the functionality of a conventional light field camera to be obtained. In contrast to a conventional light field camera, however, the camera system 1 does not require a main lens covering all photosensitive regions and imaging the object 9 to be imaged.

Consequently, the camera system 1 can be extremely flat compared to a conventional light field camera.

FIG. 1C illustrates an example in the most simplified form, using a single microlens as optical channel 3. As illustrated in FIG. 1A, more than one micro-optical element may be used instead.

As in FIG. 1B, light beams originating from points A and B of object 9 are shown in the figures. Three enlarged representations (1) to (3) in FIG. 1C illustrate how the points A and B of the object 9 are imaged onto the photodetectors 2.

In this simplified example there are two separate photodetectors 2 that image the same point of the object using different beams, namely photodetector 2A1 detecting beam ra1 and photodetector 2A2 detecting beam ra2 originating from point A. This concept can be extrapolated to a larger set of separate distributed optical channels with associated photodetectors, wherein all optical channels 3 image the same object but use different angular directions. Another set of separate distributed optical channels 3 can image another point of the object 9 using a multitude of beams as illustrated in the enlarged representation (3).

Here, photodetector 2B3 exemplarily detects beam rb3 originating from point B.

The total set of optical channels 3 with associated photodetectors 2 is able to image the object 9 with spatial resolution as well as angular resolution to act as a light field camera.

In the most simplified design, as illustrated in FIG. 1C, the photodetectors 2 may be photodetectors having exactly one photosensitive region. However, one photodetector 2 may also comprise two or more photosensitive regions, for example in order to image two or more different points of the object using two or more different beams.

As illustrated in FIG. 1A, the optical channels 3 may each comprise a plurality of micro-optical elements 35. For example, the micro-optical elements 35 are microlenses or meta-lenses or micro-optical elements based on a meta-material.

In the exemplary embodiment of FIG. 1A, the micro-optical elements 35 of the optical channels 3 are formed using a substrate 36 and a further substrate 37 extending over the detection area of the camera system 1. For example, micro-optical elements 35 can be formed on one side or on both sides of the substrates 36, 37. However, the optical channels 3 may also be formed as optical elements spaced apart from one another.

The number of micro-optical elements 35 and substrates 36, 37 can be varied within wide limits. For example, the number of micro-optical elements 35 for one optical channel 3 may be in a range from 1 to 10. For example, the substrate 36 and/or the further substrate 37 can be formed from a glass or a plastics material which is transmissive in the visible spectral range. The micro-optical elements 35 may be formed in or applied to the material of the substrates 36, 37.

The photodetectors 2 are individual devices arranged on a carrier 15 such as a printed circuit board. For example, the photodetectors 2 are photodiodes, pin photodiodes, avalanche photodiodes or single photon avalanche photodiodes.

Optionally, one or more of the photodetectors 2 may be dedicated to a certain wavelength range and/or a polarization direction. For this purpose, optical filters such as optical bandpass filters or polarization-sensitive elements may be arranged in the beam path towards the associated photodetector 2.

For example, polarization-sensitive elements may be arranged in the beam path towards one or more photodetectors 2 in order to measure polarization-dependent lighting situations, for example when detecting light being polarized by reflection at a specular surface.

Alternatively or in addition, optical channels 3 may be specifically adapted to the spectral range to be detected by the associated photodetector 2. Compared to conventional camera systems using large optics, chromatic aberrations may be avoided in this way in a facilitated manner.

Alternatively or in addition, optical channels may be comprised of pulsed or otherwise amplitude or frequency-modulated light sources to realize distance measurements, e.g. using the time-of-flight (ToF) principle and/or the self-mixing-interferometry (SMI) principle.

The camera system 1 can be integrated in or arranged behind a pane such as a glass pane as the camera system 1 does not require imaging optical elements such as a common main lens in addition to the micro-optical elements of the optical channels 3.

Even though the optical channels 3 are laterally spaced apart from one another, the optical channels 3 are capable of fulfilling the same functionality as an optical compound eye camera. Furthermore, taken together, the optical channels 3 can realize the light field principle without a main lens. This is realized by the implementation of both spatial resolution and angular resolution within the optical channels 3 in combination with the associated photodetectors 2 so that a multitude of pixels are sensitive to light entering from different directions.

The camera system 1 may further comprise additional elements such as protective layers or optical layers. For example, absorbing material may be provided between adjacent optical channels 3 and/or photodetectors 2 in order to reduce or avoid optical crosstalk.

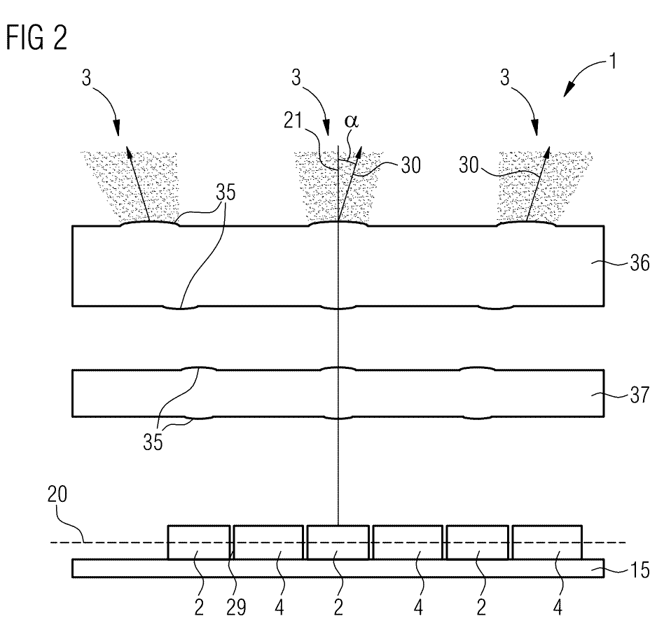

The exemplary embodiment shown in FIG. 2 essentially corresponds to the exemplary embodiment described in connection with FIG. 1A.

In the exemplary embodiment of FIG. 2, light emitters 4 are arranged in interspaces 29 between adjacent photodetectors 2.

The light emitters 4 may be part of a display or a projector. Consequently, the camera system 1 can be integrated into a display or projector system. In particular, the micro-optical elements 35 of the optical channels 3 may be formed at least in part within one or more substrates 36, 37 of the display or projector.

For example, a micro-optical element 35 of the optical channel 3 has a lateral extent that is smaller than or equal to a center-to-center distance of the light emitters 4 and/or smaller than a center-to-center pixel pitch of the display.

In particular, the lateral extent of the micro-optical element 35 may be smaller than or equal to an edge-to-edge distance between light emitters 4 forming adjacent pixels of the display in a top view onto the camera system 1.

The light emitters 4 may be micro-LEDs, wherein the term “micro-LEDs” includes both inorganic LEDs and organic LEDs (OLEDs).

As displays using micro-LEDs as pixels only require a comparably small fill factor, there is sufficient space between adjacent micro-LEDs to arrange one or more optical channels 3 and associated photodetectors 2 between them.

As the camera system 1 can be integrated into the display, for example in a smartphone, a camera- or even an additional camera for further functionality such as face recognition placed laterally beside the display can be dispensed with.

Thus, a large fraction of the display area, or even the entire display area, could be used for the camera system without negatively affecting the functionality and/or the design of the device comprising the display.

Furthermore, a user of the device looks into the camera system 1 if he looks at the display. Thus, a conversation partner in a video conference may have the impression of direct eye contact.

In the exemplary embodiment shown in FIG. 2, the light emitters 4 are arranged in the detection plane 20. Consequently, the light emitters 4 and the photodetectors 2 may be placed on and electrically connected to the same carrier 15 during production. This may even be done in a common production step.

Alternatively, at least some or even all of the light emitters 4 may be spaced apart from the detection plane 20.

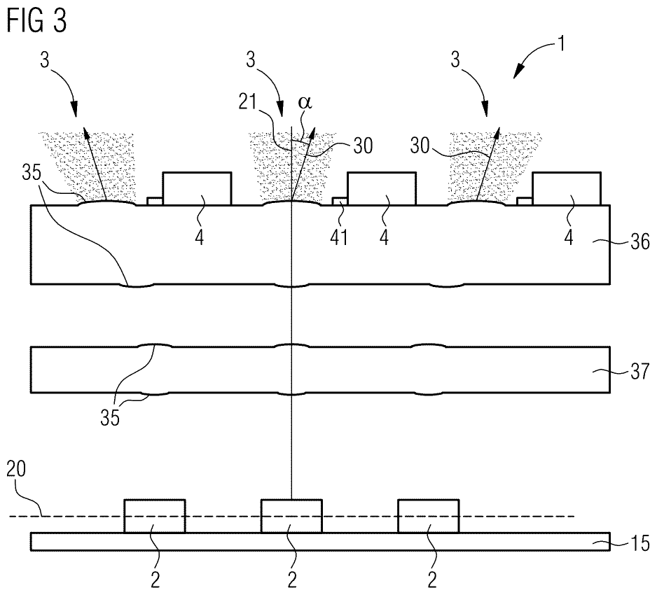

For example, FIG. 3 shows an exemplary embodiment where the light emitters 4 and conductors 41 electrically connecting the light emitters 4 are arranged on a substrate 36. At least one or even all of the micro-optical elements 35 of the optical channels 3 may be arranged at a smaller distance from the detection plane 20 than the light emitters 4. Arranging the light emitters 4 further away from the detection plane 20 may help to reduce unintended optical crosstalk between the light emitters 4 and the photodetectors 2, for example caused by reflections at the substrate 37 arranged between the detection plane 20 and the light emitters 4.

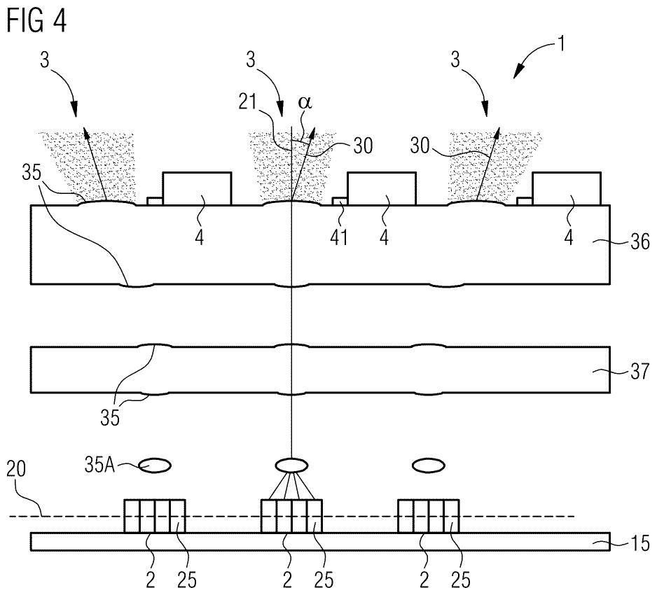

The exemplary embodiment of FIG. 4 substantially corresponds to the exemplary embodiment described in connection with FIG. 3. In departure therefrom, the photodetectors 2 each comprise a plurality of photosensitive regions 25. In this case, an edge-to-edge distance between two adjacent photodetectors 2 is larger than a distance between two adjacent photosensitive regions 25 of one photodetector 2, for example by a factor of at least 1.5 or at least 2 or at least 5 or at least 10. Such photodetectors 2 may also be used for the other exemplary embodiments.

In the exemplary embodiment of FIG. 4, a further micro-optical element 35A is arranged in a focal plane of each of the optical channels 3. This is similar to an arrangement in a conventional light field camera. These further micro-optical elements 35A help to make sure that beams originating from other locations of the object to be imaged do not hit the photodetector 2 associated to the optical channel 3. Instead of a micro-optical element a diaphragm may be used.

By means of the plurality of photosensitive regions 25 within one photodetector 2, the number of optical channels 3 may be reduced to achieve the same level of spatial and/or angular resolution.

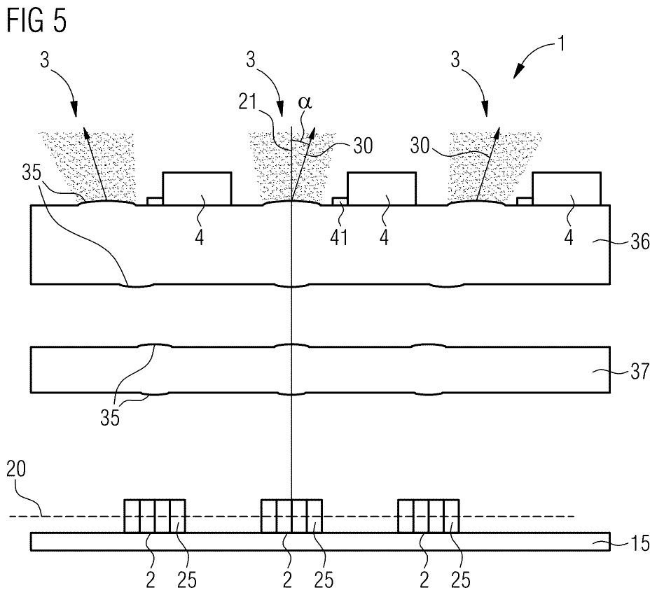

In the exemplary embodiment of FIG. 5, the photodetectors 2 comprising a plurality of photosensitive regions 25 are arranged in the focal plane of the optical channels 3. For example, the photosensitive regions 25 may be used for a parallel readout in order to avoid dead times after detection of a photon if, for example, a single photon avalanche photodiode is used for the photodetector 2 or a photosensitive region 25 thereof.

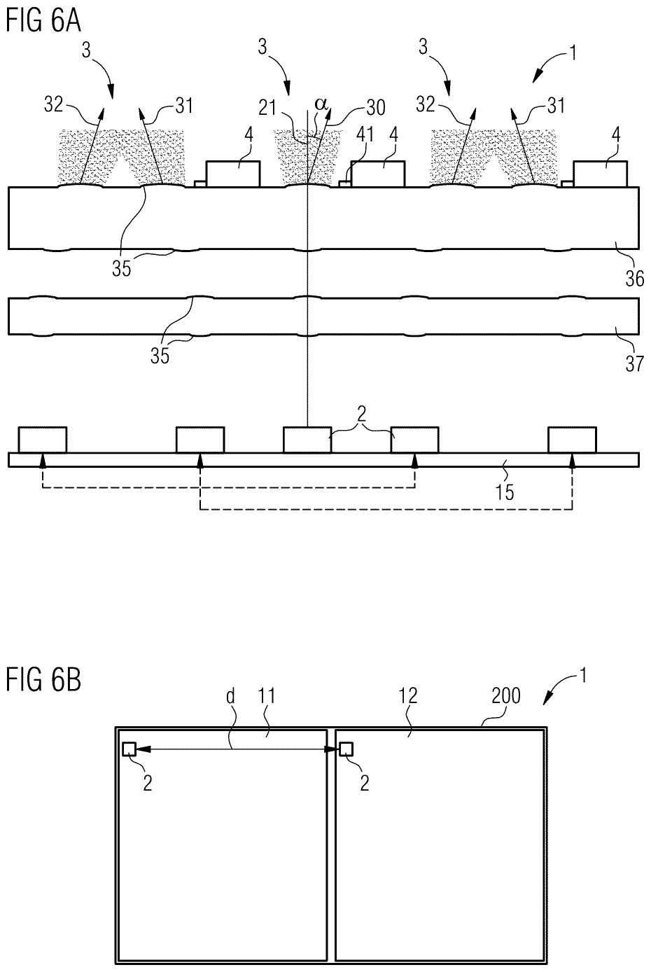

In the exemplary embodiments of FIGS. 6A and 6B, the camera system 1 is configured for stereo vision. The plurality of different main viewing directions 30 comprises a first main viewing direction 31 and a second main viewing direction 32.

As illustrated in FIG. 6A at least one of the optical channels 3 having the second main viewing direction 32 is arranged between two of the optical channels 3 having the first main viewing direction 31. Thus, photodetectors 2 acting as pixels for a “left” camera and photodetectors 2 acting as pixels for a “right” camera are intermixed in the detection plane 20. For example, such an arrangement can be used to enable stereovision only for certain areas of the total field of view of the camera system 1 or to increase the depth resolution in certain areas.

In departure therefrom, the optical channels 3 having the first main viewing direction may be arranged in a first region 11 of the detection area 200 of the camera system 1 and the optical channels having the second main viewing direction are arranged in a second region 12 of the detection area 200 of the camera system 1 arranged laterally beside the first region 11. This is illustrated in FIG. 6B.

For the sake of simplicity only one photodetector 2 is shown for each of the regions 11, 12. A distance d between these two photodetectors 2 represents the stereo basis. The photodetectors 2 within the first region 11 act as pixels of a “left” camera and the photodetectors 2 within the second region 12 act as pixels of a “right” camera or vice versa.

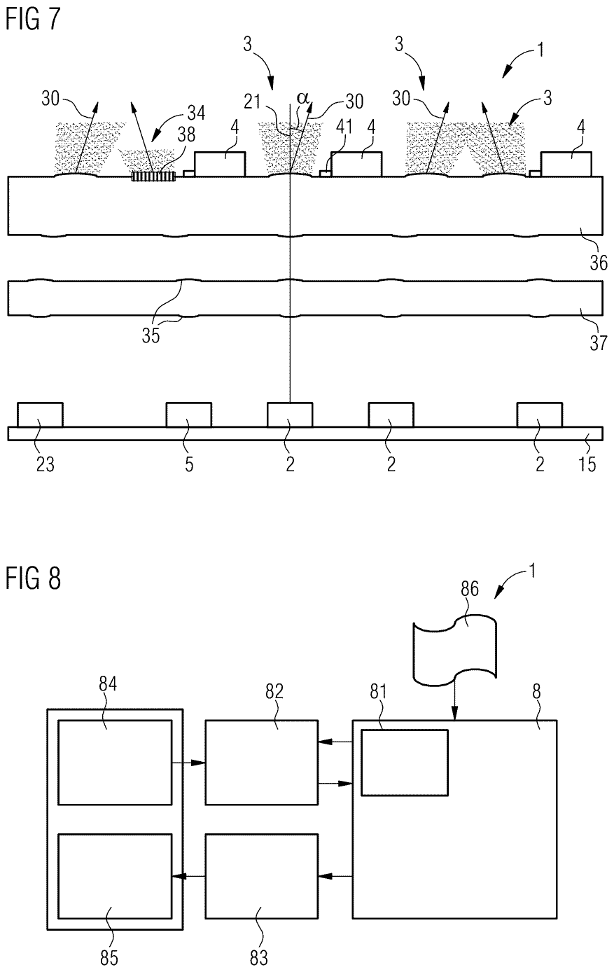

In the exemplary embodiment of FIG. 7, the camera system 1 additionally comprises a radiation source 5 configured to illuminate an object to be viewed. For example, the radiation source 5 emits radiation in the visible or in the infrared spectral range.

A further optical channel 34 is assigned to the radiation source 5 and configured to direct the radiation of the radiation source 5 onto the object to be viewed. The further optical channel 34 may be formed essentially in the same manner as the optical channels 3 used to illuminate the photodetectors 2.

Optionally a diffractive optical element 38 is arranged in the beam path of the further optical channel 34. For example, the diffractive optical element 38 may be used to create a radiation pattern on the user's face for face recognition or other biometric applications. Such a radiation source 5 may also be used in the further exemplary embodiments described above.

The camera system optionally comprises one or a plurality of further photodetectors 23 with a spectral sensitivity specifically adapted to the wavelength range of the radiation emitted by the radiation source 5, for example infrared radiation.

An exemplary embodiment of a conceptual design of the camera system 1 is illustrated in FIG. 8. A data processing system 8 is configured to extract an image from signals obtained from the plurality of photodetectors 2. For example, the data processing system 8 comprises an image processing system 81 electrically connected to an array 84 of photodetectors 2 via a readout electronics 82. Optionally, the readout electronics may include means for pre-processing the signals or data from the photodetectors 2, for example for combining the signals or data from two or more of the photodetectors 2. For example, this may be done using standard logic or architectures similar to neural networks.

The data processing system 8 is further configured to control the display 85 via a display control electronics 83. If the camera system 1 is not integrated into a display (cf. FIG. 1A and description thereof), the display control electronics 83 and the display 85 may be dispensed with. A control software 86 may be used to reconstruct the image based on the data from the array 84 of photodetectors 2, wherein the data from the array 84 may be provided to the data processing system 8 in raw and/or pre-processed form. Additional depth information may be obtained and registered in order to algorithmically perform refocusing, change the depth of focus or to generate 3D information on the object to be viewed.

This patent application claims the priority of German patent application 10 2023 116 560.7, the disclosure content of which is hereby incorporated by reference.

The invention described herein is not restricted by the description given with reference to the exemplary embodiments. Rather, the invention encompasses any novel feature and any combination of features, including in particular any combination of features in the claims, even if this feature or this combination is not itself explicitly indicated in the claims or exemplary embodiments.

### REFERENCES

1 camera system
11 first region
12 second region
15 carrier
2 photodetector
2A1, 2A2, 2A3 photodetector
2B1, 2B2, 2B3 photodetector
20 detection plane
200 detection area
21 normal
23 further photodetector
25 photosensitive region
29 interspace
3 optical channel
30 main viewing direction
31 first main viewing direction
32 second main viewing direction
34 further optical channel
35 micro-optical element
35A further micro-optical element
36 substrate
37 further substrate
38 diffractive optical element
4 light emitter
41 conductor
5 radiation source
8 data processing system
81 image processing system
82 readout electronics
83 display control electronics
84 array of photodetectors
85 display
86 control software
9 object
2 angle
d distance
ra1, ra2, ra3 beam
rb1, rb2, rb3 beam

1. A camera system comprising a plurality of photodetectors and a plurality of optical channels, wherein
the plurality of photodetectors are arranged spaced apart from one another in a detection plane,
to each one of the plurality of photodetectors one of the plurality of optical channels is assigned,
each of the plurality of optical channels has a main viewing direction, and
the plurality of optical channels comprise a plurality of different main viewing directions.

2. The camera system according to claim 1,
wherein, in a top view onto the camera system, light emitters are arranged at least in some interspaces between two adjacent photodetectors.

3. The camera system according to claim 2,
wherein the light emitters are micro-LEDs.

4. The camera system according to claim 2,
wherein at least some of the light emitters are arranged in the detection plane.

5. The camera system according to claim 2,
wherein at least some of the light emitters are arranged on a substrate that is spaced apart from the detection plane

6. The camera system according to claim 5,
wherein at least some of the light emitters are arranged at a larger distance from the detection plane than at least one micro-optical element of one of the plurality of optical channels.

7. The camera system according to claim 1,
wherein the camera system comprises a radiation source configured to illuminate an object to be imaged.

8. The camera system according to claim 7,
wherein a radiation from the radiation source is directed onto the object to be imaged via a further optical channel assigned to the radiation source.

9. The camera system according to claim 1,
wherein the camera system is configured for stereo vision.

10. The camera system according to claim 1,
wherein the plurality of different main viewing directions comprises a first main viewing direction and a second main viewing direction wherein, in a top view onto the camera system, each of the plurality of optical channels having the first main viewing direction are arranged in a first region of the camera system and each of the plurality of optical channels having the second main viewing direction are arranged in a second region of the camera system arranged laterally beside the first region

11. The camera system according to claim 1,
wherein the plurality of different main viewing directions comprises a first main viewing direction and a second main viewing direction, wherein, in a top view onto the camera system, at least one of the plurality of optical channels having the second main viewing direction is arranged between two of the plurality of optical channels having the first main viewing direction.

12. The camera system according to claim 1,
wherein at least one of the plurality of photodetectors includes at least one of a photodiode, a pin-photodiode, an avalanche photodiode (APD), and a single photon avalanche diode (SPAD).

13. The camera system according to claim 1,
wherein at least one of the plurality of photodetectors includes a plurality of photosensitive regions.

14. The camera system according to claim 1,
wherein the camera system comprises a data processing system configured to extract an image from signals obtained from the plurality of photodetectors.

15. The camera system according to claim 14,
wherein the data processing system is configured to extract a depth information on the image.

16. A camera system comprising a plurality of photodetectors and a plurality of optical channels, wherein
the plurality of photodetectors are arranged spaced apart from one another in a detection plane,
to each one of the plurality of photodetectors one of the plurality of optical channels is assigned,
each of the plurality of optical channels has a main viewing direction, and
the plurality of optical channels comprise a plurality of different main viewing directions,
in a top view onto the camera system, light emitters are arranged at least in some interspaces between two adjacent photodetectors, wherein optical channels with the associated photodetectors are configured to image an object.
